(19) United States
(12) Patent Application Publication
(10) Pub. No.: US 2018/0096909 A1
(43) Pub. Date: Apr. 5, 2018

(54) SEMICONDUCTOR DEVICE HAVING TWO ENCAPSULANTS

(71) Applicant: NXP B.V., Eindhoven (NL)

(72) Inventors: Wanwisa Peerapaisansap, Bangkok (TH); Rungnattha Katworapattra, Bangkok (TH); Aricha Olarnwanich, Bangkok (TH)

(21) Appl. No.: 15/286,428

(22) Filed: Oct. 5, 2016

(51) Int. Cl. H01L 23/31; H01L 23/495; H01L 23/00; H01L 21/56; H01L 23/29

(52) U.S. Cl. CPC H01L 23/3135; H01L 2924/0665; H01L 23/49541; H01L 24/49; H01L 24/06; H01L 24/83; H01L 21/56; H01L 24/85; H01L 24/92; H01L 23/315; H01L 23/293; H01L 2224/32245; H01L 2224/48091; H01L 2224/48106; H01L 2224/48247; H01L 2224/73265; H01L 2224/92247; H01L 2924/17747; H01L 2224/2919; H01L 2224/83851; H01L 2224/45144; H01L 2224/45147; H01L 2924/186; H01L 23/3121

(57) ABSTRACT

A semiconductor device includes a substrate, a semiconductor die mounted on and electrically connected to the substrate, and first and second encapsulants that are different from each other. The first encapsulant covers the die and at least part of the substrate. The second encapsulant covers the first encapsulant and a portion of the substrate that is not covered by the first encapsulant.

### BACKGROUND

The present invention generally relates to a semiconductor device and a method for packaging a semiconductor device, and more particularly, to a contactless communication device and a method for packaging the same.

A typical semiconductor device includes a semiconductor die and a lead frame. The lead frame includes multiple leads for being connected to bonding pads of the semiconductor die such as by clip bonding, wire bonding, or flip-chip. A combination of the semiconductor die and the lead frame is then sealed with an encapsulant, which provides electrical and mechanical protection to the semiconductor die, the lead frame, and the connections therebetween.

Risks that packaged semiconductor devices may be damaged increase with their widening usage, especially in applications as portable devices, contactless communication devices, etc. It is an object of the present invention to provide protection to a packaged semiconductor device such that the semiconductor device can be used as a wearable device, and/or in challenging environments.

### SUMMARY

This summary is provided to introduce a selection of concepts in a simplified form that are further described below in the Detailed Description. This summary is not intended to identify key or essential features of the claimed subject matter, nor is it intended to be used to limit the scope of the claimed subject matter.

In one embodiment, the present invention provides a semiconductor device that includes a substrate, a semiconductor die, and first and second encapsulants. The semiconductor die is mounted on and electrically connected to the substrate. The first encapsulant covers the die and at least part of the substrate. The second encapsulant covers the first encapsulant and a portion of the substrate that is not covered by the first encapsulant. Further, the second encapsulant is different from the first encapsulant.

In another embodiment, the present invention provides a method for packaging a semiconductor device. The method includes mounting and electrically connecting a semiconductor die to a substrate, sealing, with a first encapsulant, the substrate and the die, and applying a second encapsulant over the first encapsulant, where the second encapsulant is different from the first encapsulant.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments. The drawings are for facilitating an understanding of the invention and thus are not necessarily drawn to scale. Advantages of the subject matter claimed will become apparent to those skilled in the art upon reading this description in conjunction with the accompanying drawings, in which like reference numerals have been used to designate like elements, and in which:

FIGS. 1 and 2 are enlarged cross-sectional side views illustrating steps of packaging a semiconductor device in accordance with an exemplary embodiment of the present invention; and

FIGS. 3 is an enlarged cross-sectional side view of the semiconductor device of FIG. 2 in use as a contactless communication card.

### DETAILED DESCRIPTION

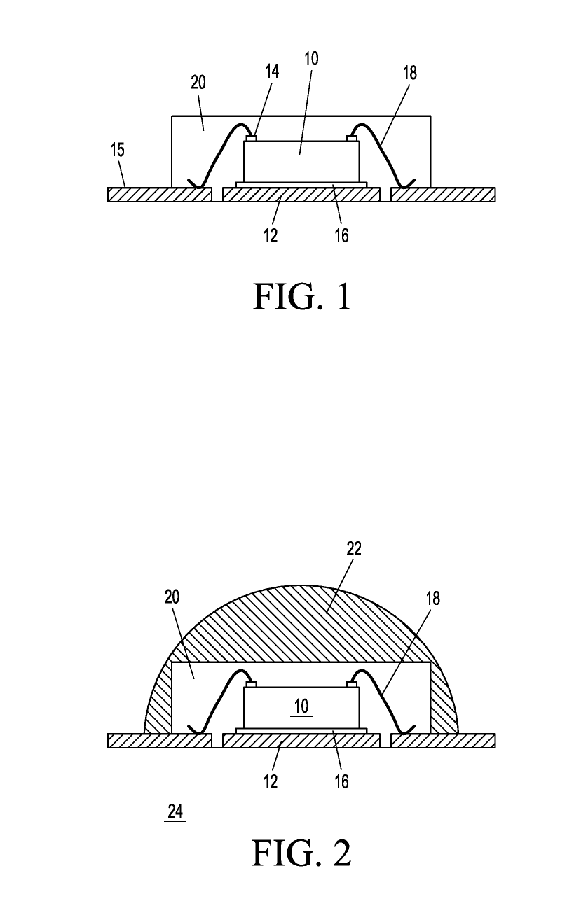

FIGS. 1 and 2 are cross-sectional views illustrating steps of assembling or packaging a semiconductor device in accordance with an exemplary embodiment of the present invention. Referring to FIG. 1, a semiconductor die 10 is mounted on a substrate 12. The semiconductor die 10 can be fabricated through any wafer fabrication process to have a desired functionality. The semiconductor die 10 has bond pads 14 for connecting the die internal circuitry to external circuitry. The substrate 12 can be prefabricated, such as a lead frame with leads or lead fingers 15 that allow for external connection to the semiconductor device. The substrate 12 can be formed of Cu, copper alloy, etc., and may be plated, as is known in the art.

The semiconductor die 10 is mounted on and attached to the substrate 12 with an adhesive 16 or tape, as is known in the art. In one embodiment, the adhesive 16 is thermally conductive, so that heat generated by the semiconductor die 10 can be dissipated through the substrate 12. In another embodiment, the adhesive 16 is both electrically and thermally conductive for providing additional connection between the semiconductor die 10 and the substrate 12. In one embodiment, the adhesive 16 comprises an epoxy paste and be printed onto a surface of the substrate 12. After the semiconductor die 10 is attached to the substrate 12 with the adhesive 16, the adhesive 16 is cured so that the semiconductor die 10 and the substrate 12 are electrically and physically connected.

The semiconductor die 10 may have an active region on one side thereof and a non-active region on an opposite side. In one embodiment, the semiconductor die 10 is placed on the substrate 12 such that the non-active region side faces the substrate 12. In another embodiment, the active region side of the semiconductor die 10 can be configured to face the substrate 12. In applications where the semiconductor die 10 generates heat (e.g., a power die), the substrate 12 can be used to dissipate the heat through contact between the active region side of the semiconductor die 10 and the substrate 12.

When the semiconductor die 10 is mounted on the substrate with its non-active region side attached to the substrate 12, then bond wires 18 are provided for electrically connecting the semiconductor die 10 to the substrate 12. That is, the die bond pads 14 are electrically connected to the leads 15 of the substrate 12 with the bond wires 18. The bond wires 18 can be any kind of bond wires, such as copper or gold, and may be coated or uncoated.

It will be understood by those of skill in the art that the electrical connection of the semiconductor die 10 to the substrate 12 is not limited to the above-mentioned wire bonding. In alternative embodiments, clip bonding, flip-chip, etc. also may be used. For example, in one embodiment the semiconductor die 10 is attached to the substrate 12 with the die bond pads 14 facing the substrate 12, and electrically connected to the leads 15 on the substrate 12 with conductive adhesive.

In one exemplary application, the semiconductor device comprises a contactless communication device, e.g., a contactless card or RFID tag, where the substrate 12 is patterned to form or be further connected to an antenna that is configured to send and/or receive signals from/to the semiconductor die 10.

After attaching and electrically connecting the semiconductor die 10 to the substrate 12, a first encapsulant 20 is provided to cover the semiconductor die 10, the substrate 12 and the electrical connections therebetween—e.g., the bond wires 18. In the presently preferred embodiment, the first encapsulant 20 comprises an epoxy-resin composition, for example a C-stage plastic material (Resite). The first encapsulant 20 is applied such that it covers and seals the semiconductor die 10 and at least part of the substrate 12. The first encapsulant 20 is subsequently cured to be physically hard, so that the semiconductor die 10, the substrate 12 and the bond wires 18 covered by the first encapsulant 20 are protected from potential environmental influences like moisture and dust, as well as mechanical damage. The encapsulant 20 may be formed over the die 10 and the substrate 12 using known methods, such as transfer molding.

Referring to FIG. 2, a second encapsulant 22 is applied over the cured first encapsulant 20. In the presently preferred embodiment, the second encapsulant 22 is materially different from the first encapsulant 20. In one embodiment, the second encapsulant 22 comprises a material that is softer than the first encapsulant 20. For example, the second encapsulant 22 may comprise a B-stage material (Resitol). The second encapsulant 22 is elastic such that the finally assembled semiconductor device is better protected from mechanical damage. For example, in its applications as a contactless communication card/tag, the semiconductor device experiences vibrations during daily use, the elastic second encapsulant 22 is able to absorb at least some of the vibrations so that the semiconductor die 10 and the substrate 12 are shielded and therefore less likely to be compromised or damaged.

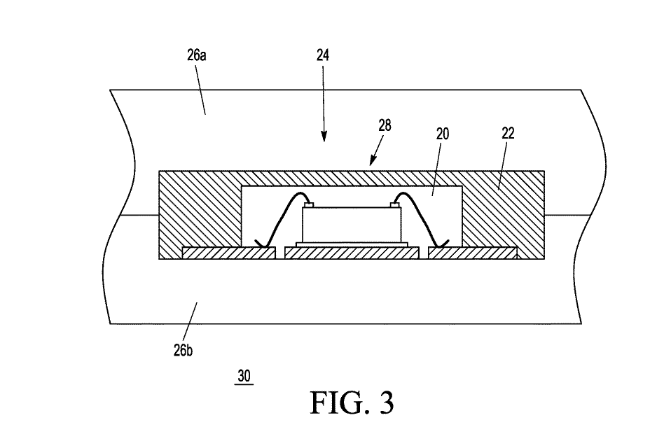

The second encapsulant 22 covers the first encapsulant 20 and a portion of the substrate 12 that is not covered by the first encapsulant 20. In one embodiment, the second encapsulant 22 has an arcuate outline, as shown in FIG. 2. In other embodiments, the second encapsulant 22 has an outline akin to but extending over the profile of the first encapsulant 20 (see FIG. 3). The second encapsulant 22 may be formed over the first encapsulant 20 by depositing corresponding colloidal or fluent material drops on the first encapsulant 20 before being cured. The die 10 and substrate 12 covered by the first and second encapsulants 20 and 22 comprises an assembly 24.

FIG. 3A is an enlarged cross-sectional view of a contactless communication card 30. The contactless communication card 30 comprises the assembly 24 shown in FIG. 2, i.e., die 10, substrate 12, bond wires 18 and first and second encapsulants 20 and 22 (although in this embodiment the second encapsulant 22 follows the form of the first encapsulant 20). The device 30 also includes lamination layers 26a and 26b. In one embodiment, to assemble the contactless communication card 30, multiple lamination layers 26a, 26b are provided and the assembly 24 is sandwiched between the lamination layers 26a, 26b. The lamination layers 26a, 26b receive and sandwich the assembly 24 therebetween. The elastic second encapsulant 22 is re-activated to flow and, with the sandwiching pressure and heat, the second encapsulant 22 fills the gaps between the lamination layers 26 and the cured first encapsulant 20 and the substrate 12.

The lamination layers 26a, 26b can be made from PVC or PET materials, and can be prepared as having a card outline before assembling with the assembly 24. In one embodiment, the lamination layers 26a, 26b are include recesses on their opposing surfaces. The recesses jointly form a cavity 28 when the lamination layers 26a, 26b are laminated together. The cavity 28 receives the assembly 24 therein, and the elastic second encapsulant 22 is heated so that it flows to fill any gaps between the neighboring lamination layers, e.g., the cavity sidewall, and the assembly 24.

It is possible to have only one of the lamination layers 26a or 26b with a recess for forming the cavity. For example, the lamination layer 26a can have a flat surface that faces the lamination layer 26b, which has a recess that receives the assembly 24 therein. The lamination layer 26a covers the recess of the lamination layer 26b and provides a cavity accordingly. In yet another embodiment, the lamination layer 26b has a flat surface that receives the assembly 24 thereon, and the lamination layer 26a has a recess that mates with the lamination layer 26b with the assembly 24 received in the recess.

In accordance with FIG. 3, the assembly 24 can be sandwiched between the lamination layers 26 with the elastic B-stage encapsulant 22 surrounding the semiconductor die 10 and the C-stage encapsulant 20, and filling any gaps between the assembly 24 and the lamination layers 26a, 26b. In use, the contactless communication card 30 endures mechanical stresses that are absorbed by the elastic material 22, such that the elastic material 22 effectively protects the semiconductor die 10 and its external connections.

The use of the terms “a” and “an” and “the” and similar referents in the context of describing the subject matter (particularly in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. Furthermore, the foregoing description is for the purpose of illustration only, and not for the purpose of limitation, as the scope of protection sought is defined by the claims as set forth hereinafter together with any equivalents thereof entitled to. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the invention as claimed.

Preferred embodiments are described herein, including the best mode known to the inventor for carrying out the claimed subject matter. Of course, variations of those preferred embodiments will become apparent to those of ordinary skill in the art upon reading the foregoing description. The inventor expects skilled artisans to employ such variations as appropriate, and the inventor intends for the claimed subject matter to be practiced otherwise than as specifically described herein. Accordingly, this claimed subject matter includes all modifications and equivalents of the subject matter recited in the claims appended hereto as permitted by applicable law. Moreover, any combination of the above-described elements in all possible variations thereof is encompassed unless otherwise indicated herein or otherwise clearly contradicted by context.

1. A semiconductor device, comprising:
a substrate;
a semiconductor die mounted on and electrically connected to the substrate;
a first encapsulant covering the die and at least part of the substrate;
a second encapsulant covering the first encapsulant and a portion of the substrate that is not covered by the first encapsulant, wherein the second encapsulant is different from the first encapsulant.

2. The semiconductor device of claim 1, wherein the substrate comprises a lead frame.

3. The semiconductor device of claim 1, wherein the first encapsulant comprises C-stage material.

4. The semiconductor device of claim 3, wherein the second encapsulant comprises B-stage material.

5. The semiconductor device of claim 1, wherein the second encapsulant is softer than the first encapsulant.

6. The semiconductor device of claim 1, further comprising bond wires connecting contact pads on the die with electrical contacts of the substrate.

7. The semiconductor device of claim 1, wherein the die includes bond pads that are facing the substrate and electrically connected to corresponding electrical contacts of the substrate with conductive adhesive.

8. The semiconductor device of claim 1, further comprising one or more lamination layers sandwiching the substrate, the die and the first encapsulant, wherein the second encapsulant fills respective gaps between the substrate, the die, the first encapsulant and corresponding neighboring lamination layers.

9. The semiconductor device of claim 8, wherein the lamination layers have a cavity for receiving the substrate, the die and the first encapsulant, and wherein the second encapsulant fills the cavity and covers the substrate, the die and the first encapsulant.

10. A method for packaging a semiconductor device, comprising:
mounting on and electrically connecting a semiconductor die to a substrate;
sealing, with a first encapsulant, the substrate and the die;
applying a second encapsulant over the first encapsulant, wherein the second encapsulant is different from the first encapsulant.

11. The method of claim 10, wherein mounting and electrically connecting the die to the substrate comprises:
placing the die on the substrate; and
wire bonding bond pads of the die with corresponding electrical contacts on the substrate with bond wires.

12. The method of claim 10, wherein mounting and electrically connecting the die to the substrate comprises:
placing the die on the substrate such that bond pads on a surface of the die face the substrate; and
connecting, with a conductive adhesive, the die bond pads with corresponding electrical contacts of the substrate.

13. The method of claim 10, wherein the first encapsulant comprises C-stage material.

14. The method of claim 13, wherein the second encapsulant comprises B-stage material.

15. The method of claim 10, wherein the second encapsulant is softer than the first encapsulant.

16. The method of claim 10, wherein the substrate comprises a lead frame.

17. The method of claim 10, wherein the substrate comprises an antenna for sending and receiving signals from/to the die.

18. The method of claim 10, further comprising one or more lamination layers sandwiching the substrate, the die and the first encapsulant therebetween, wherein the second encapsulant fills gaps between the substrate, the die, the first encapsulant and corresponding neighboring lamination layers.

19. The method of claim 18, wherein the lamination layers have a cavity for receiving the substrate, the die and the first encapsulant, and the second encapsulant fills the cavity and covers the substrate, the die and the first encapsulant.
